(19) United States
(12) Patent Application Publication
(10) Pub. No.: US 2012/0279943 A1
(43) Pub. Date: Nov. 8, 2012

(54) PROCESSING CHAMBER WITH COOLED GAS DELIVERY LINE

(75) Inventors: Helinda Nominanda, Santa Clara, CA (US); Tae Kyung Won, San Jose, CA (US); Seon-Mee Cho, San Jose, CA (US); Beom Soo Park, San Jose, CA (US); Soo Young Choi, Fremont, CA (US)

(73) Assignee: Applied Materials, Inc., Santa Clara, CA (US)

(21) Appl. No.: 13/462,939

(22) Filed: May 3, 2012

Related U.S. Application Data
(60) Provisional application No. 61/481,904, filed on May 3, 2011.

(51) Int. Cl. C23C 16/50; B05C 9/00; B44C 1/22; C23C 16/511

(52) U.S. Cl. 216/69; 118/723 R; 118/723 AN; 427/569; 427/575; 156/345.33; 216/67

(57) ABSTRACT

A method and apparatus for processing a substrate is provided. In one embodiment, the apparatus is in the form of a processing chamber that includes a chamber body having a processing volume defined therein. A substrate support, a gas delivery tube assembly and a plasma line source are disposed in the processing volume. The gas delivery tube assembly includes an inner tube is disposed in an outer tube. The inner tube has a passage for flowing a cooling fluid therein. The outer tube has a plurality of gas distribution apertures for providing processing gas into the processing volume.

### CROSS REFERENCE TO RELATED APPLICATION

This application claims benefit of U.S. Provisional Patent Application Ser. No. 61/481,904, filed May 3, 2011, which is incorporated by reference in its entirety.

### BACKGROUND

1. Field

Embodiments of the present invention are generally relates to plasma processing of substrates, and more specifically, to cooling of gas delivery lines in a plasma processing chamber.

2. Description of the Related Art

Chemical vapor deposition and other plasma processes may be performed utilizing a processing chamber having a microwave plasma generation source. In such conventional chambers, processing gas is often provided through gas distribution tubes extending through the processing volume of the processing chamber. As these tubes are exposed to the microwave energy used to form a plasma, the tubes are subject to thermal expansion which may cause the tubes to physically bend within the processing volume, thereby altering the gas distribution within the chamber. If the gas distribution alters within the chamber, processing results may be adversely affected.

FIG. 1 is a sectional view of a conventional processing chamber 100. The processing chamber 100 includes a chamber body 102 coupled to a pumping system 104, a gas delivery system 106 and one or more power sources 130. The chamber body 102 defines a processing volume 116 in which a substrate support 118 is disposed. The substrate support 118 holds a substrate 120 during processing. A slit valve passage 112 is formed through the chamber body 102 to allow entry and egress of a substrate 120 from the processing volume 116. The slit valve passage 112 is selectively sealed by a slit valve 114.

A pumping port 122 is formed in the chamber body 102 and coupled to the pumping system 104. The pumping system 104 is utilized to regulate the pressure within the processing volume 116, and to remove process by-products during processing of the substrate 120.

Process and other gases are provided into the processing volume 116 through a plurality of gas delivery tubes 128. The gas delivery tubes 128 have a plurality of apertures (not shown) which allow process gases provided by the gas delivery system 106 to enter the processing volume 116.

Gases within the processing volume 116 are energized using a plurality of plasma line source 124 coupled to the one or more power sources 130. In the embodiment depicted in FIG. 1, the plasma line sources 124 are a plurality of microwave antennas which are coupled to the power source 130. Nom In operation, gases provided from the gas delivery tubes 128 are energized by the microwave power applied by the plasma line sources 124. The energized process gases decompose and deposit as a film on the substrate 120 disposed on the substrate support 118. The energy provided by the plasma line sources 124 additionally heat the gas delivery tubes 128, causing the gas delivery tubes 128 to deflect laterally, as shown by arrows 110, as the gas delivery tube expands. The deflection in the gas delivery tube creates a non-uniform distribution of process gases within the processing volume 116, which contributes to non-uniform processing results. In order to minimize the deflection of the gas delivery tubes 128 during processing, the gas delivery tubes 128 may be coupled in one or more places to the chamber body 102 by brackets 132. However, processing results indicate that the brackets 132 contribute to non-uniform processing results due to disturbance of gas flow within the processing volume 116.

Thus, there is a need for an improved gas delivery tube for use within a processing chamber.

### SUMMARY

A method and apparatus for processing a substrate is provided. In one embodiment, the apparatus is in the form of a processing chamber that includes a chamber body having a processing volume defined therein. A substrate support, a gas delivery tube assembly and a plasma line source are disposed in the processing volume. The gas delivery tube assembly includes an inner tube is disposed in an outer tube. The inner tube has a passage for flowing a cooling fluid therein. The outer tube has a plurality of gas distribution apertures for providing processing gas into the processing volume.

In one embodiment, a method for plasma processing a substrate is provide that includes transferring a substrate into a plasma processing chamber, flowing process gas between an inner tube and an outer tube, the processing gas flowing into a processing volume defined in the processing chamber through gas distribution apertures formed in the outer tube, energizing the processing gas in the processing volume; processing the substrate in the presence of the energized processing gas, and flowing a cooling fluid through the inner tube.

### BRIEF DESCRIPTION OF THE DRAWINGS

So that the manner in which the above recited features of the present disclosure can be understood in detail, a more particular description, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional view of a conventional plasma processing chamber;

FIG. 2 is a cross-sectional view of an illustrative plasma processing chamber having one embodiment of a gas delivery tube assembly;

FIG. 3 is a partial cross-sectional view of the processing chamber of FIG. 3 illustrating the gas delivery tube assembly in greater detail;

FIG. 4 is a graph comparing processing results obtained utilizing the processing chambers of FIGS. 1 and 2; and

FIG. 5 is a cross-sectional view of another illustrative plasma processing chamber having another embodiment of a gas delivery tube assembly;

FIG. 6 is a partial cross-sectional view of the processing chamber of FIG. 5 illustrating the gas delivery tube assembly in greater detail.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

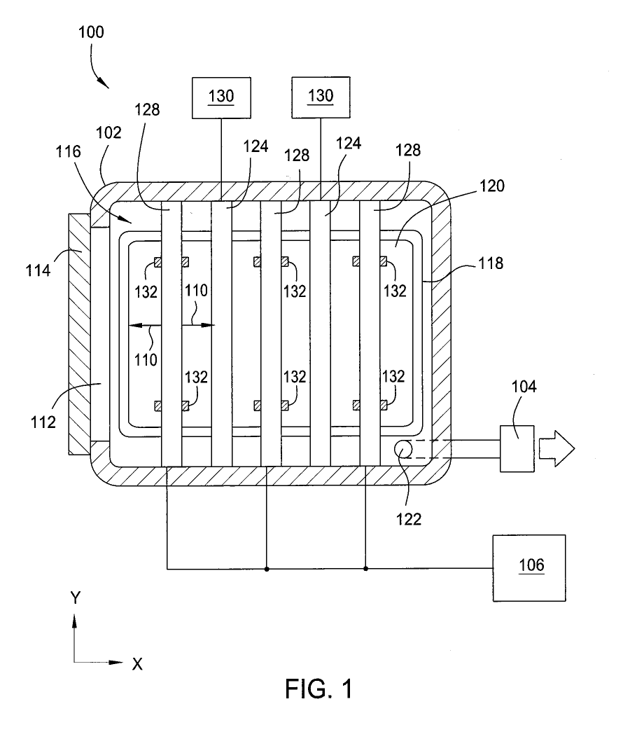

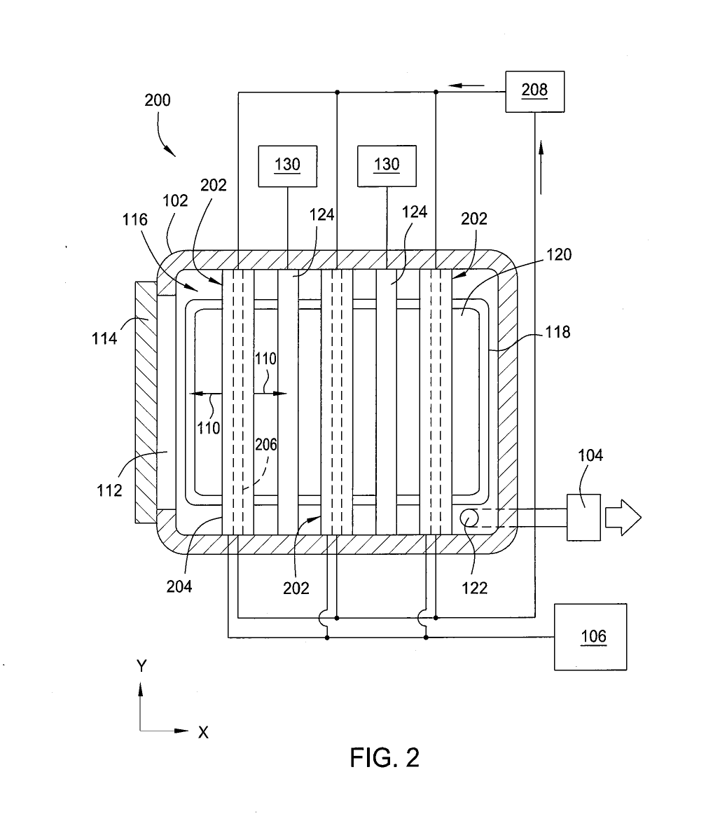

FIG. 2 is a sectional view of an illustrative processing chamber 200 having one embodiment of a gas delivery tube assembly 202 of the present invention. The processing chamber 200 is substantially similar to the processing chamber 100 of FIG. 1, except wherein the gas delivery tube assembly 202 is disposed in the processing volume 116 to distribute gas provided by the gas delivery system 106 for processing a substrate.

The gas delivery tube assembly 202 includes an inner tube 206 circumscribed by an outer tube 204. The inner tube 206 is coupled to a cooling fluid source 208. The cooling fluid is circulated from the cooling fluid source 208 through the inner tube 206 to control the temperature of the gas delivery tube assembly 202, thereby minimizing the thermal expansion and lateral deflection (as shown by arrows 110) of the gas delivery tube assembly 202 during processing. The gases provided by the gas delivery system 106 flow through the outer tube 204 which circumscribes the inner tube 206. The tubes 204, 206 are generally fabricated from a plasma-resistant material, such as aluminum. Although three gas delivery tube assemblies 202 are shown, any number may be utilized, for example, N+1 tube assemblies 128 for N number of plasma line sources 124. In another embodiment, one line source 124 may be utilized for each 300 mm of substrate length in the x direction, while one gas delivery tube assembly 202 may be utilized for each 100 mm of substrate length in the x direction.

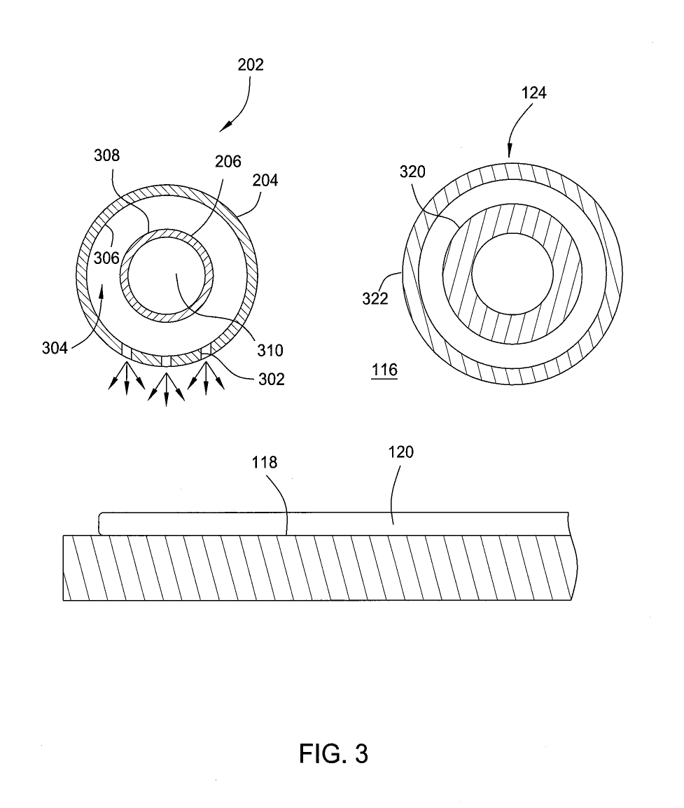

FIG. 3 depicts a partial sectional view of the processing chamber 200 illustrated in FIG. 2 illustrating the gas delivery tube assembly 202 in greater detail. The gas delivery tube assembly 202 has a plurality of gas distribution apertures 302 formed through the outer tube 204. A plenum 304 is defined between an inner diameter wall 306 of the outer tube 204 and an outer diameter wall 308 of the inner tube 206. Gases provided by the gas delivery system 106 flow into the plenum 304. The plenum 304 is substantially large enough to allow the gases within the plenum 304 to be maintained at a substantially equal pressure along the length of the gas delivery tube assembly 202, thereby allowing the gases to enter the processing volume 116 uniformly through the gas distribution apertures 302. Although the gas distribution apertures 302 are illustrated as formed through one side of the outer tube 204, i.e., the side of the tube 204 facing the substrate support 118, it is contemplated that the gas distribution apertures 302 may be equally distributed around the circumference of the outer tube 204, or be arranged in another suitable location. In the embodiment depicted in FIG. 3, the gas distribution apertures 302 are arranged in multiple rows extending axially down one side of the outer tube 204.

A passage 310 is defined within the inner tube 206 and coupled to the cooling fluid source 208. The cooling fluid flows through the passage 310, thereby regulating the temperature of the inner tube 206. The cooling fluid may be a liquid or gas, or a combination of both. The cooling fluid should not be reactive to the process gas in case of leakage from the inner tube 206. As the process gas in the plenum 304 provides a heat transfer medium between the inner tube 206 and the outer tube 204, the fluid flowing through the passage 310 of the inner tube 206 also regulates the temperature of the outer tube 204. Thus, the fluid flowing through the passage 310 of the inner tube 206 may be utilized to regulate the thermal expansion of the tube assembly 202, and thereby minimizing deflection, as shown by arrow 110 illustrated in FIG. 2.

The plasma line source 124 is also illustrated in FIG. 3. In the embodiment depicted in FIG. 3, the plasma line source 124 includes a hollow conductive tube 320 which is coupled to the power source 130 and circumscribed by a ceramic tube 322. During operation, energy radiating from the plasma line source 124 may heat the outer tube 204. The temperature of the fluid flowing through the passage 310 may be controlled such that the temperature of the tube assembly 202 is substantially constant from the beginning to the end of the deposition or other plasma process by balancing the energy received from the plasma line source 124 with the heat removed by the fluid in the passage 310.

Returning to FIG. 2, the fluid flowing from the cooling fluid source 208 through the inner tube 206 is shown by circulating through the cooling fluid source 208. Additionally, the cooling fluid is illustrated as passing through the tube assemblies 202 in a uniform direction. Alternatively, the direction of the cooling fluid provided by the cooling fluid source 208 may flow in opposite directions through adjacent gas delivery tube assemblies 202, for example, flowing in the (+) y direction in one tube, then flowing in the (−) y direction in the neighboring gas delivery tube assembly, then flowing again in the (+) y direction in the next adjacent gas delivery tube assembly 202, and so on.

As illustrated in the embodiment depicted in FIG. 2, the gas delivery tube assemblies 202 extend from at least one sidewall of the chamber body 202 into the processing volume 116. The gas delivery tube assemblies 202 may be supported on opposite ends by the chamber body 202. Due to the efficient removal of thermal energy from the gas delivery tube assembly 202 by the cooling fluid, deflection, as shown by arrow 110, is minimized, thereby eliminating the need for brackets 132, such as shown in conventional processing chamber 100 of FIG. 1, to prevent the gas delivery tube assembly 202 from deflecting. The absence of brackets in the processing chamber 200 advantageously removes potential gas flow disturbances, thereby enhancing the attainment of uniform gas flow and more uniform processing results.

In operation, a substrate is transferred into the plasma processing chamber 200. Process gas from the gas delivery system 106 is provided the plenum 304 defined between the inner tube 206 and the outer tube 204 of the gas delivery tube assembly 202, and flows from the plenum 304 into processing volume 116 through the apertures 302 formed in the outer tube 204. Power is provided to the plasma line sources 124, thereby energizing the processing gas within the processing volume 116, for example, by forming a plasma. The substrate 120 is processed in the presence of the energized processing gas. In one embodiment, substrate 120 is processed by a chemical vapor deposition process. In alternative embodiments, the substrate 120 may be processed by implanting dopants into the surface of the substrate 120, etching the substrate 120, or annealing the substrate 120, among other substrate processes.

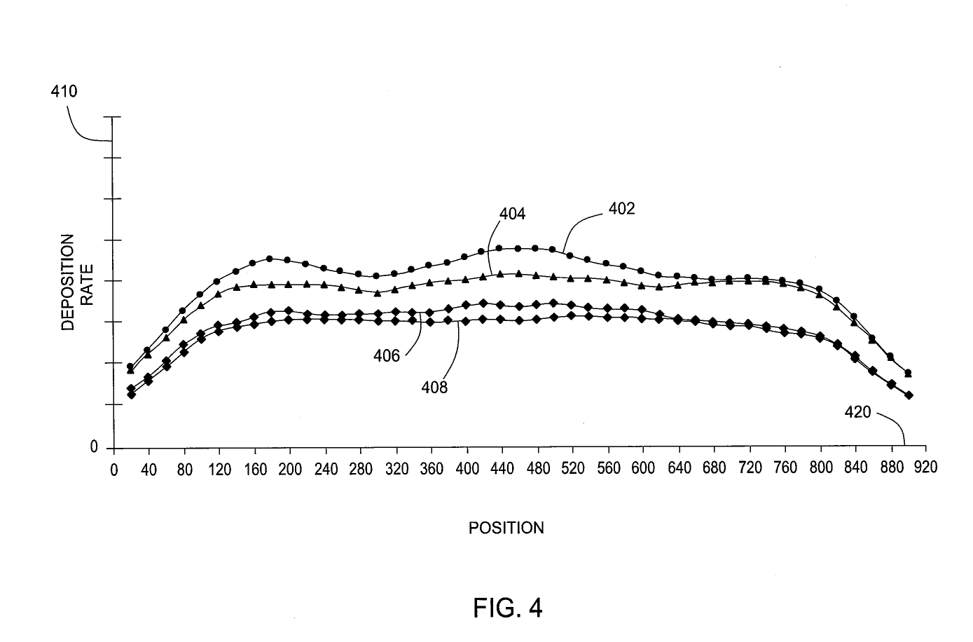

FIG. 4 is a chart comparing the processing results obtained utilizing the conventional processing chamber 100 illustrated in FIG. 1 with and without the use of brackets 132. The deposition rate is illustrated on the axis 410 while the lateral position of the gas delivery tube relative a substrate is illustrated on axis 420. Traces 202, 204 illustrate deposition results utilizing the processing chamber 100 of FIG. 1 with brackets 132 utilized to support the gas delivery tubes 128, while traces 604, 608 illustrate processing results using the processing chamber 100 of FIG. 1 with brackets 132 supporting the gas delivery tubes 128 removed. As illustrated in FIG. 4, the deposition traces 206, 204 have more uniform deposition rates compared to traces 202, 204. Thus, as the processing chamber 200 does not utilized brackets 132, and the distribution assembly 202 has substantially less deflection as compared to the gas delivery tubes 128 used without brackets 132, the temperature controlled gas distribution assembly 202 will yield even more uniform deposition results than that which may be obtained utilizing gas delivery tubes 128, with or without brackets. The benefits of the invention are not limited to the configuration illustrated in FIG. 2. For examples, it is contemplated that the number, position, orientation and pattern of the apertures 302 may vary. It is also contemplated that the tubes 204, 206 may be concentric, non-concentric or have another orientation relative each other. It is also contemplated that the one or more of the tubes 204, 206 need not be cylindrical as shown. Additionally, it is contemplated that the novel gas delivery tube assemblies 202 may be utilized in other industries or CVD technologies where prevention of deflection due to thermal expansion is desirable.

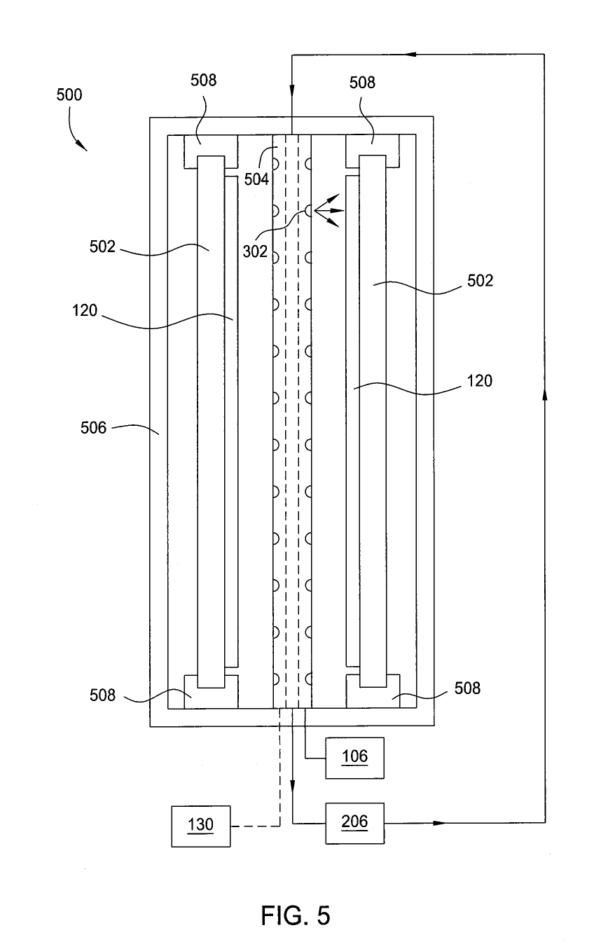

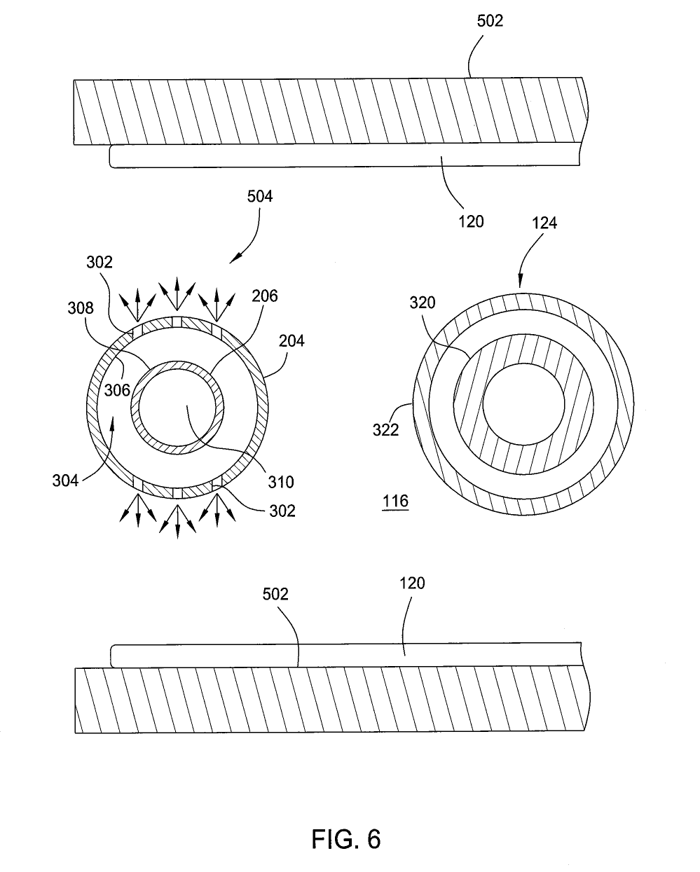

FIG. 5 is a sectional view of another illustrative processing chamber 500 having another embodiment of a gas delivery tube assembly 504 of the present invention. The processing chamber 500 is substantially similar to the processing chamber 200 of FIG. 2, except wherein the gas delivery tube assembly 504 is disposed in processing volume 116 to distribute gas provided by the gas delivery system 106 for processing two substrates 120, the substrates 120 disposed opposite sides of the gas delivery tube assembly 504. Although only one gas delivery tube assembly 504 is illustrated in FIG. 6, a plurality of gas delivery tube assemblies 504 are utilized in the chamber 500, for example, arranged in a row in the center of the chamber 500 such the arrangement of gas delivery tube assemblies 202 illustrated in FIG. 2.

The processing chamber 500 includes a chamber body 506 configured to process two substrates 120 simultaneously in a common chamber volume. The substrates 120 may be transported into the processing volume 116 of the chamber body 506 on carriers 502. The carriers 502 are supported by rollers or tracks 508 which may include a drive mechanism (not shown) for moving the carriers 502 within the chamber body 506, or maybe a passive mechanism, such as roller, that relies on another mechanics, such as an external transfer mechanism (i.e., robot) to move the carriers 502 into and out of the chamber body 506. An example of a processing chamber that may be modified to incorporate the gas delivery tube assembly 504 of the present invention is described in U.S. patent application Ser. No. 13/098,253, filed Apr. 29, 2011, which is incorporated by reference in its entirety.

Referring additionally to the partial sectional view of the processing chamber 500 depicted in FIG. 6, the gas delivery tube assembly 504 includes an inner tube 206 circumscribed by an outer tube 204. The plasma line source 124 is also illustrated in FIG. 6 and is configured as described above.

The inner tube 206 is coupled to a cooling fluid source 208. The cooling fluid is circulated from the cooling fluid source 208 through the inner tube 206 to control the temperature of the gas delivery tube assembly 504, thereby minimizing the thermal expansion and lateral deflection (i.e., towards the substrates 120) of the gas delivery tube assembly 504 during processing. The gases provided by the gas delivery system 106 flow through the outer tube 204 which circumscribes the inner tube 206. As discussed above, any number of gas delivery tube assemblies 504 may be utilized, for example, N+1 tube assemblies 504 for N number of plasma line sources 124. In another embodiment, one line source 124 may be utilized for each 300 mm of substrate length in the x direction, while one gas delivery tube assembly 504 may be utilized for each 100 mm of substrate length in the x direction.

The gas delivery tube assembly 504 has a plurality of gas distribution apertures 302 formed through the outer tube 204. The gas distribution apertures 302 may be located on opposites sides of the tube 204, for example, about 180 degrees apart. The arrangement of gas distribution apertures 302 on opposites sides of the tube 204 directs gas in opposite directions and towards each of the substrates, while not directing gas towards the line sources 124, thereby more efficiently using the process gas for deposition on the substrate while minimizing deposition in unwanted areas, such as the line source 124, from process directed orthogonal to the substrate or other part of the chamber 500.

A plenum 304 is defined between an inner diameter wall 306 of the outer tube 204 and an outer diameter wall 308 of the inner tube 206. Gases provided by the gas delivery system 106 flow into the plenum 304. The plenum 304 is substantially large enough to allow the gases within the plenum 304 to be maintained at a substantially equal pressure along the length of the gas delivery tube assembly 504, thereby allowing the process gases to be directed uniformly through the gas distribution apertures 302 to each substrate 120. Although the gas distribution apertures 302 are illustrated as formed in multiple rows on opposite sides of the outer tube 204, i.e., the sides of the tube 204 facing each substrate 120, it is contemplated that the gas distribution apertures 302 may be arranged in a single row. In the embodiment depicted in FIG. 6, the gas distribution apertures 302 are arranged in multiple rows axially extending down opposite sides of the outer tube 204.

As discussed above, a passage 310 is defined within the inner tube 206 and coupled to the cooling fluid source 208. The cooling fluid flows through the passage 310, thereby regulating the temperature of the inner tube 206. As the process gas in the plenum 304 provides a heat transfer medium between the inner tube 206 and the outer tube 204, the fluid flowing through the passage 310 of the inner tube 206 also regulates the temperature of the outer tube 204. Thus, the fluid flowing through the passage 310 of the inner tube 206 may be utilized to regulate the thermal expansion of the tube assembly 504, and thereby minimizing deflection, similar to as shown by arrow 110 illustrated in FIG. 2.

As illustrated in the embodiment depicted in FIG. 5, the gas delivery tube assemblies 504 extend from at least one sidewall of the chamber body 504 into the processing volume 116. The gas delivery tube assemblies 504 may be supported on opposite ends by the chamber body 504. Due to the efficient removal of thermal energy from the gas delivery tube assembly 504 by the cooling fluid, deflection towards the substrate 120 is minimized, thereby improving deposition uniformity without the need for brackets. The absence of brackets in the processing chamber 500 advantageously removes potential gas flow disturbances, thereby enhancing the attainment of uniform gas flow and more uniform processing results.

Thus, an improved method and apparatus for plasma processing a substrate has been provided. The temperature control gas distribution assembly tube provides more uniform processing results than similarly configured conventional processing chambers, thereby enabling more robust processing results and better substrate-to-substrate uniformity.

While the foregoing is directed to embodiments of the present invention, other and further embodiments of the invention may be devised without departing from the basic scope thereof, and the scope thereof is determined by the claims that follow.

1. A processing chamber comprising:
a chamber body having a processing volume defined therein;
a substrate support disposed in the processing volume;
a plasma line source disposed in the processing volume; and
a gas delivery tube assembly disposed in the processing volume adjacent the plasma line source, the gas delivery tube assembly comprising:
an outer tube extending into the processing volume and having a plurality of gas distribution apertures; and
an inner tube disposed within the outer tube and having a passage configured to flow a cooling fluid therein.

2. The processing chamber of claim 1, wherein the outer tube extends from a sidewall of the chamber body.

3. The processing chamber of claim 1, wherein the outer tube is supported at opposite ends from the chamber body.

4. The processing chamber of claim 1, wherein the outer tube is fabricated from aluminum.

5. The processing chamber of claim 1, wherein the plasma line source comprises:
a microwave antenna.

6. The processing chamber of claim 1, wherein the outer tube is parallel to the plasma line source.

7. The processing chamber of claim 1, wherein the outer tube is perpendicular to the plasma line source.

8. The processing chamber of claim 1, wherein the inner tube and outer tube are concentric.

9. The processing chamber of claim 1, wherein a plenum is defined between the outer tube and the inner tube.

10. The processing chamber of claim 1, wherein the plurality of gas distribution apertures plurality of gas distribution apertures are arranged to direct gas in two opposing directions from the outer tube.

11. A processing chamber comprising:
a chamber body having a processing volume defined therein;
a substrate support disposed in the processing volume;
a plurality of plasma line sources disposed in the processing volume; and
a plurality of gas delivery tube assemblies disposed in the processing volume, at least one of the gas delivery tube assemblies comprising:
an outer tube extending into the processing volume and having a plurality of gas distribution apertures; and
an inner tube disposed within the outer tube and having a passage configured to flow a cooling fluid therein, wherein a plenum is defined between the inner and outer tubes.

12. The processing chamber of claim 11, wherein the plurality of plasma line sources comprises N+1 tube assemblies for N number of plasma line sources.

13. The processing chamber of claim 12, wherein the plurality of plasma line sources comprises microwave antennas.

14. A method for plasma processing a substrate comprising:
transferring a substrate into a plasma processing chamber; flowing process gas through a plenum defined between an inner tube and an outer tube and through apertures formed in the outer tube into a processing volume defined in the processing chamber;
energizing the processing gas in the processing volume;
processing the substrate in the presence of the energized processing gas; and
flowing a cooling fluid through the inner tube.

15. The method of claim 14, wherein the fluid flowing in the inner tube comprises a liquid.

16. The method of claim 14, wherein the fluid flowing through the inner tube comprises a gas.

17. The method of claim 14, wherein the fluid flowing in the inner tube comprises a gas and liquid mixture.

18. The method of claim 14, wherein energizing the gas present in the processing volume comprises:
applying microwave power to an antenna extending into the process volume.

19. The method of claim 14, wherein plasma treating the substrate further comprises depositing a layer of material on the substrate.

20. The method of claim 14, wherein plasma treating the substrate further comprises at least one of etching, annealing or implanting a dopant on the substrate.
